(19) United States
(12) Patent Application Publication
(10) Pub. No.: US 2010/0112814 A1
(43) Pub. Date: May 6, 2010

(54) PRE-CERTIFIED PROCESS CHAMBER AND METHOD

(76) Inventor: Sowmya Krishnan, Union City, CA (US)

Correspondence Address: King & Spalding LLP, P.O. Box 889, Belmont, CA, 94002-0889, US

(21) Appl. No.: 11/995,925

(22) PCT Filed: Sep. 5, 2007
(86) PCT No.: PCT/US2007/019411

§ 371 Date: Dec. 11, 2008

Related U.S. Application Data
(60) Provisional application No. 60/842,503, filed on Sep. 6, 2006.

(51) Int. Cl. H01L 21/285; C23C 16/54

(52) U.S. Cl. 438/680; 118/715; 118/663; 257/E21.17

(57) ABSTRACT

The present invention relates generally to the field of semiconductor device manufacturing and more specifically to the manufacture and certification of semiconductor processing equipment. Systems and methods are described that establish a baseline contamination levels at each stage of the manufacture, assembly, testing, and installation of a process chamber.

### FIELD OF THE INVENTION

The present invention relates generally to the field of semiconductor device manufacturing and more specifically to the manufacture and certification of semiconductor processing equipment. The present invention relates generally to the field of process chamber surface preparation, cleaning, and analysis.

### BACKGROUND OF THE INVENTION

Advanced microelectronic devices are being manufactured with ever increasing device density and complexity. The device dimensions are decreasing in both the lateral and vertical directions. Smaller device elements allow for increasingly complex, faster, and more powerful devices. The multitude of layers and materials used in the construction of these advanced devices are being deposited by a number of well known techniques comprising low pressure thermal chemical vapor deposition (LPCVD), plasma enhanced chemical vapor deposition (PECVD), atmospheric pressure chemical vapor deposition (APCVD), physical vapor deposition (PVD), thermal conversion of the substrate, and the like.

The high device density and small device dimensions are driving increasingly stringent requirements and specifications for contaminants on the devices. These contamination requirements comprise specifications for both physical particles and chemical contaminants. For economy of language, in this context, “physical contaminants” may comprise any foreign matter not intended to be deposited onto the semiconductor substrate and will be referred to henceforth by the well known semiconductor industry term as “particles”. Particles may be composed of metals, alloys, dielectrics, ceramics, inorganic matter, organic matter, biological matter, combinations thereof, and the like. Chemical contaminants may be understood as chemical species that become exposed to the semiconductor substrate and react to become incorporated into some portion of the device. The chemical contaminants may be incorporated in any of the layers or regions of the device comprising the base substrate, active regions, contact regions, epitaxial layers, dielectric layers, conductor layers, barrier layers, encapsulation layers, combinations thereof, and the like.

The particles may produce a number of problems in the manufacture of the semiconductor device comprising open interconnections, shorted interconnections, poor contact resistance, exposed layers, film delamination, and the like. Chemical contaminants may produce a number of problems in the manufacture of the semiconductor device comprising introduction of contaminants into the device, variation of etch rates, variation of deposition rates, growth of unwanted compounds, formation of particles in the gas phase, corrosion of parts of the semiconductor processing equipment

The strict requirements and specifications for contaminants on the devices may have a profound impact on the manufacture, cleaning, certification, and maintenance of the equipment used to manufacture the devices. Many portions of the semiconductor processing equipment may be impacted by these requirements. Examples of the various portions of the semiconductor processing equipment may comprise the process chamber, delivery lines used to introduce gases or liquids into the process chamber, internal parts of the process chamber, chambers used to store the semiconductor substrates, chambers and assemblies used to transport the semiconductor substrates within the semiconductor processing equipment, and the like.

The manufacture, cleaning, certification, and maintenance of many portions of the equipment used to manufacture the devices have matured to meet these stringent requirements. As an example, delivery lines and systems used to supply liquids and gases to the semiconductor processing equipment are typically manufactured, cleaned, and certified to levels of less than 20 parts per million (ppm) for contaminants comprising total hydrocarbons (THC), moisture, and the like. These subsystems follow well documented procedures whereby they are manufactured, cleaned, inspected, and certified before being delivered to the customer. The customer may comprise the original equipment manufacturer (OEM), a subassembly manufacturer, the end user (i.e. device manufacturer), or the like.

However, there are not similar procedures for the manufacture, cleaning, inspection, and certification of the process chambers used in semiconductor processing equipment. Typically, the surface area of the process chambers used in semiconductor processing equipment will be several orders or magnitude greater than the surface area of the delivery lines used to deliver liquids and gases to the process chambers. Typically, procedures may exists for the cleaning of the process chambers during their manufacture and their assembly into the semiconductor processing equipment, but there are no procedures for the inspection, and certification of the process chambers. As mentioned previously, the existence of particles and contaminants inside the process chamber may introduce a number of problems during the manufacture of the semiconductor device. The initial contamination may lead to problems comprising variable results during initial system installation, increased time for system qualification, wafer-to-wafer and run-to-run variation during system qualification, system matching across a device fabrication facility, and the like. These problems may lead to issues comprising poor manufacturing, subassembly, testing, installation, qualification, and troubleshooting procedures. These issues result in long manufacturing times, higher manufacturing costs, inefficient use of resources, poor quality, poor customer satisfaction, long maintenance cycles, and the like.

Therefore, a need exists in the art for systems and methods for the manufacture, cleaning, inspection, and certification of the process chambers used in semiconductor processing equipment to decrease the variability of the initial results, shorten the time for qualification, and improve the system matching across a device fabrication facility, and the like.

### BRIEF SUMMARY OF THE INVENTION

In the invention includes, in one aspect, a process chamber designed for use in a semiconductor processing system having one or more such chambers, where each chamber in the system is designed to receive a substrate and a process gas that acts upon the substrate, as part of a process for producing a semiconductor device. The chamber is pre-certified to contain no more than a predetermined threshold concentration of a contaminant that is known to adversely affect the performance characteristics of such a device, when produced in such a process, and sealed with an inert gas to prevent exposure of the chamber to the atmosphere prior to being incorporated into the system.

The chamber may be pre-certified to contain no more than a preselected level of one or more of total hydrocarbons (THCs), oxygen, and moisture, where the pre-certified level of the contaminant gas may be selected from within the range of 1 ppb to 100 ppm.

Also disclosed is a method for pre-certifying a process chamber designed for use in a semi-conductor processing system containing one or more such chambers. The method includes the steps of: (i) setting a pre-certification level of each of one or more contaminant gases, this level being below that at which a semi-conductor processing step designed to be carried out in that chamber may be adversely affected, (ii) heating the interior of the chamber to a temperature effective to desorb each such gas contaminant from interior surface of the chamber, (iii) during the heating step, directing a stream of inert gas stream through the chamber, thus to entrain desorbed contaminant gas in the gas stream, (iv) measuring the level of each such contaminant gas entrained in the gas stream from step (iii), (v) continuing steps (ii)-(iv) until the level of each such contaminant is at or below the pre-certification level, and (vi) sealing the chamber with an inert gas to prevent exposure of the chamber to the atmosphere.

Steps (ii)-(iv) may be carried out to achieve a pre-certification level in a selected range between 1 ppb and 100 ppm, of one or more of total hydrocarbons (THCs), oxygen, and moisture. Heating step (ii) may include heating interior surfaces of the chamber to a temperature between about 100°-400° C., preferably between 150° C.-250° C.

In another aspect, the invention includes a method of minimizing the time required to decontaminate a process chamber designed for use in a semi-conductor processing system containing one or more such chambers, to achieve a preselected level of one or more contaminant gases, where the preselected level of contaminant gas is below that at which a semi-conductor processing step designed to be carried out in that chamber may be adversely affected. The method includes the steps of: (i) heating the interior of the chamber to a temperature effective to desorb each such gas contaminant from interior surface of the chamber, (ii) during the heating step, directing a stream of inert gas stream through the chamber, thus to entrain desorbed contaminant gas in the gas stream, (iii) at each of a plurality of time points following the initiation of step (i), measuring the level of each such contaminant gas entrained in the gas stream from step (ii), thus to determine the rate of desorption of each contaminant gas under the conditions of steps (i) and (ii), and (iv) calculating from the rate of desorption of each contaminant gas determined in step (iii), the minimum time required to achieve such preselected level of the contaminant gas having the slowest rate of desorption from the chamber walls.

The contaminant gas measured in step (iii) may be one or more of total hydrocarbons (THCs), oxygen, and moisture, where the preselected level of contaminant gas is less than a preselected level in the range 1 ppb to 100 ppm.

In a related aspect, the invention includes a method of decontaminating a process chamber designed for use in a semi-conductor processing system containing one or more such chambers, to achieve a preselected level one or more contaminant gases, said preselected level of a contaminant gas being below that at which a semi-conductor processing step designed to be carried out in that chamber may be adversely affected. The method includes the steps of: (i) heating the interior of the chamber to a temperature effective to desorb each such gas contaminant from interior surface of the chamber, (ii) during the heating steps, directing a stream of inert gas stream through the chamber, thus to entrain desorbed contaminant gas in the gas stream, (iii) continuing step (i)-(ii) for a period of time calculated, on the basis of a predetermined rate of desorption of each contaminant gas under the conditions of step (i) and (ii), to achieve such preselected level of the contaminant gas having the slowest rate of desorption from the chamber walls.

In another aspect, the invention includes a semiconductor processing system comprising: (a) a process chamber; (b) a heater for heating interior walls of the process chamber to a selected temperature between about 100°-400° C.; (c) a purge-gas supply line for directing an inert purge gas through the chamber; (d) a device for measuring a concentration of a contaminant in the process chamber; and (e) a controller operatively connected to the heater, supply line and measuring device, for periodically reducing the level of selected contaminant gases in the chamber to below-threshold levels. The controller is designed to carry out the steps of (i) heating the interior of the chamber to a temperature effective to desorb each such gas contaminant from interior surface of the chamber, (ii) during the heating step, directing a stream of inert gas stream through the chamber, thus to entrain desorbed contaminant gas in the gas stream, and (iii) continuing step (i)-(ii) for a period of time calculated, on the basis of a predetermined rate of desorption of each contaminant gas under the conditions of step (i) and (ii), to achieve such preselected level of the contaminant gas having the slowest rate of desorption from the chamber walls.

In still another aspect, a controller in a semiconductor processing system of the type described above is operable for periodically reducing the level of selected contaminant gases in the chamber to below-threshold levels, by the steps of:(i) heating the interior of the chamber to a temperature effective to desorb each such gas contaminant from interior surface of the chamber, (ii) during said heating, directing a stream of inert gas stream through the chamber, thus to entrain desorbed contaminant gas in the gas stream, (iii) continuing step (i)-(ii) for a period of time calculated, on the basis of a predetermined rate of desorption of each contaminant gas under the conditions of step (i) and (ii), to achieve such preselected level of the contaminant gas having the slowest rate of desorption from the chamber walls.

In another aspect, the invention includes a computer readable code for carrying out the above steps under the control of a controller in a semiconductor processing system of the type described above.

These and other objects and features of the invention will be more fully appreciated when the following detailed description of the invention is read in conjunction with the accompanying drawings.

### BRIEF DESCRIPTION OF THE DRAWINGS

FIG. 1 schematically represents one embodiment of a semiconductor processing system comprising a plurality of process chambers.

FIG. 2 schematically represents a cross section of one embodiment of a process chamber used in a semiconductor processing system.

FIG. 3 is a flow diagram of steps in certifying a chamber, in accordance with an embodiment of the invention.

FIG. 4 is a schematic representation of a system constructed in accordance to an embodiment of the invention.

FIGS. 5A-5B are flow diagrams of steps for determining a rate of desorption of contaminants from a chamber, in accordance with an embodiment of the invention (5A) and for decontaminating a chamber under minimized time conditions, in accordance with another embodiment of the invention (5B).

### DETAILED DESCRIPTION OF THE INVENTION

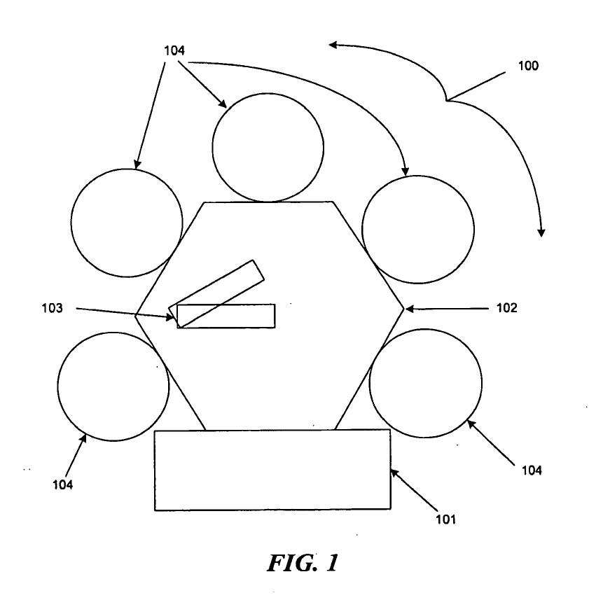

FIG. 1 schematically represents one embodiment of a semiconductor processing system comprising a plurality of process chambers. In this figure, the semiconductor processing system, 100, is comprised of substrate handling subassembly, 101, transfer hub, 102, transfer robot, 103, and a plurality of process chambers, 103. Semiconductor process equipment may comprise any number of process chambers from one to eight or more. Additionally, other variations of this generic semiconductor process equipment may comprise other features and subassemblies not explicitly shown in this schematic. This exemplary representation does not limit the teaching of the present invention in any way.

A plurality of substrates is typically contained within a holder and is placed in the substrate handling subassembly, 101. Silicon wafers for use as substrates for the manufacture of semiconductor devices will be used as examples. However, the substrates may comprise compound semiconductors, flat panel displays, substrates for MEMS (micro electronic mechanical systems) devices, substrates for photonic devices, substrates for thin film head manufacture, polymers, ceramics, and the like. This exemplary use of silicon wafers does not limit the teaching of the present invention in any way. Typically, the wafers may be transferred from the cassette into one of the process chambers, 104, by transfer robot, 103, passing through transfer hub, 102. The transfer may occur at atmospheric pressure or may occur at a reduced pressure. The most common practice makes the transfer at a reduced pressure. In the case of transfer at a reduced pressure, there may be an intermediate loadlock chamber (not shown) between the substrate handling subassembly and the transfer hub or the substrate handling subassembly may have the ability to be evacuated to a reduced pressure. The specific process method associated with that process chamber is then practiced and the wafer may be returned to the cassette or may be transferred to another process chamber for the practice of additional process methods. Finally, the wafer is returned to the cassette and the cassette may be sent to the next processing system for additional steps in the manufacture of the devices.

Each of the subassemblies indicated in FIG. 1 must be manufactured so that the wafers do not become contaminated while being processed within the system. Typically, the number of particles added by each subassembly may be measured during the installation, start-up, and qualification of the system using various methods well known in the art. Additionally, it may be possible to measure the chemical composition of contaminants that become deposited on the surface of the wafer during the installation, start-up, and qualification of the system using various methods well known in the art. However, it may difficult to determine where the source of the contamination lies. This difficulty may be enhanced when the chemical composition of the contamination does not match the chemical composition of the parts of the subassemblies.

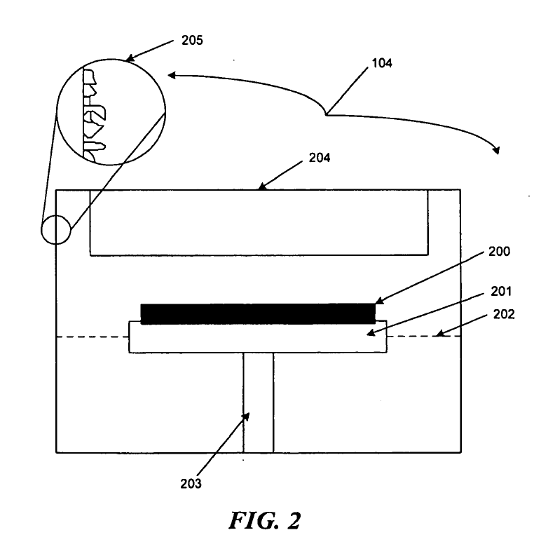

Referring now to FIG. 2, a schematic representation of a cross section of one embodiment of a process chamber, 104, used in a semiconductor processing system is shown. FIG. 2 illustrates a wafer, 200, held by a chuck, 201, which is supported by pedestal, 203. This figure illustrates a means to introduce liquids or gases, 204, above the wafer used to practice the desired process method on the wafer. Shields, 202, protect the lower portion of the process chamber from the upper portion and serve to reduce the volume of the reaction zone to improve the process method. It may be appreciated by those skilled in the art that this is one of a plurality of possible process chamber configurations. This exemplary representation does not limit the teaching of the present invention in any way. Exemplary process methods that may be practiced in similar process chambers comprise atmospheric pressure chemical vapor deposition (APCVD), low pressure chemical vapor deposition (LPCVD), plasma enhanced chemical vapor deposition (PECVD), physical vapor deposition (PVD), atomic layer deposition, (ALD), epitaxial deposition (EPI), rapid thermal annealing (RTA), thermal conversion of the substrate, vapor cleaning of the substrate, substrate heating, substrate cooling, combinations thereof, and the like.

Typically, the body of the process chamber, 104, may be a machined metal part. Popular process chamber body materials comprise aluminum, stainless steel, various nickel alloys, and the like. The machining methods used to fabricate the process chamber body may use a wide variety of organic and inorganic fluids for lubrication, cooling, corrosion resistance, and the like. Typically, these fluids must be completely removed so that they do not later contaminate the substrate during processing. The basic procedures used to remove these contaminants have been established by the chamber fabricating companies. Typically, the process chambers may be cleaned by the fabrication company and then shipped to the OEM or to a contract subassembly company. During the subassembly activity, the process chambers may be exposed to ambient air, assembly personnel, and the like. This may result in the walls of the process chamber becoming contaminated with various substances comprising water vapor, organic compounds, inorganic compounds, biological compounds, combinations thereof, and the like, in particular, water vapor (moisture), oxygen, and total hydrocarbons (THC). During the stage in the manufacture of the semiconductor process equipment, it is not possible to practice many of the common cleaning methods that would be required to clean these surfaces since the equipment cannot be submerged in the cleaning fluids. Therefore, it may only be possible to wipe the surfaces with cloths soaked in water or slightly polar solvents such as isopropyl alcohol (IPA), and the like. These treatments may not be sufficient to remove all of the contaminants from the walls of the process chamber.

Typically, any contaminants that remain on the walls of the process chamber may outgas and contaminate the wafers later during the practice of the desired process method. This may be especially true during the initial start-up and qualification of the system at the customer's manufacturing site. This may be evidenced in the high contamination levels, poor repeatability, poor uniformity, increased variability, and the like that are typically observed during this phase of the equipment qualification. The amount of contamination may slowly decrease in time as the contaminants outgas from the walls. The outgassing of the contaminants may be accelerated by features of the process method. Examples of process method features that may increase the outgassing rate comprise heat, the use of plasma, the use of reactive gases, and the like. An artistic rendition of the surface of the process chamber as may be envisioned under magnification is illustrated in FIG. 2, 205. As may be seen from the illustration, the surface of the process chamber may be very rough on a molecular or atomic scale. This results in a very large effective surface area, much larger than would be calculated by considering the dimensions of the chamber. The large surface area may serve to collect and adsorb a high concentration of contaminants that may outgas during later processing.

The systems and methods of some embodiments of the present invention, methods provide procedures to inspect, clean, and certify process chambers before they are shipped to the next stage of the manufacture of the system. The procedures may provide validation that the surface of the process chamber meets a requested contamination specification and provides data that may serve as a baseline for re-testing the chamber at various phases throughout the equipment manufacturing process and after installation at the customer's manufacturing facility.

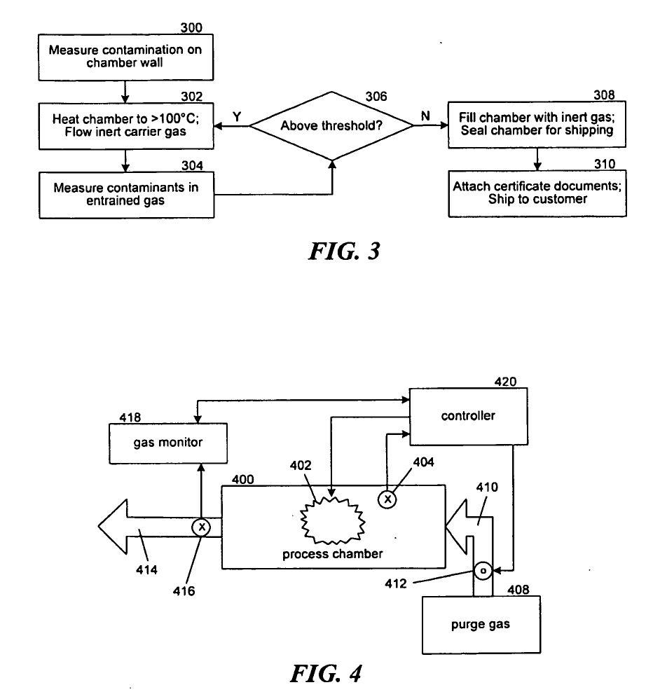

In one embodiment of the invention, the procedures follow the flow chart illustrated in FIG. 3. The contamination levels of gas contaminants adsorbed to the process chamber walls may be measured as indicated in step, 300, according the known methods (see below) Contaminants of particular interest are moisture (water vapor), oxygen, and total hydrocarbons, (THC), although other contaminants associated with microfabrication methods may also be measured.

In practicing the method, the chamber is heated to a temperature of at least 100° C., preferably no greater than 400° C., and typically between 150° C. and 250° C., such as 200° C. The heat serves to increase the rate at which contaminants that are adsorbed onto the process chamber walls outgas, or desorb. The heat source may be external (e.g. heater blankets) or internal (e.g. cartridge heaters, heater lamps, etc.) to the process chamber. Additionally, other methods for increasing the outgassing rate may be employed singly or in combination with the heat. Examples of other methods comprise ultraviolet light, plasma, pump/purge cycles, and the like.

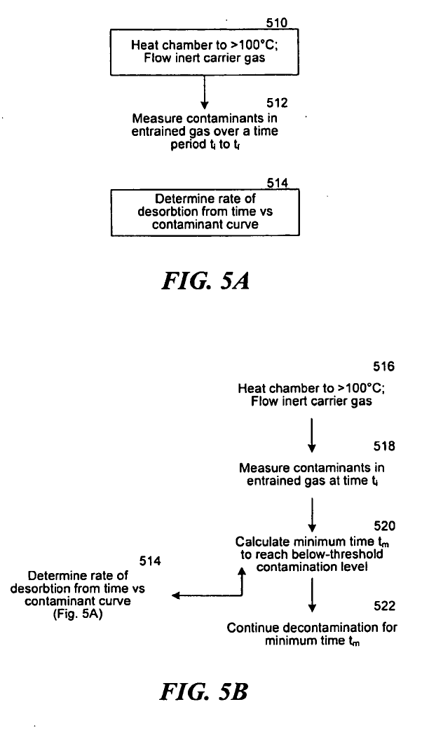

Before the chamber reaches the desired outgassing temperature, or at a selected time thereafter, an inert carrier gas is flowed through the chamber. The carrier gas serves to carry contaminants that are desorbed from the process chamber walls out of the chamber. Examples of suitable inert gases comprise N₂, He, Ne, Ar, Kr, Xe, combinations thereof, and the like. Advantageously, the inert gas comprises N₂. The heating and purging step 302 may be continued for a prescribed length of time. In some embodiments of the present invention, the prescribed time may be about 2 hours, and in another embodiment, discussed below with respect to FIGS. 5B and 5B, the heating and purging steps are optimized with respect to required outgassing time needed.

The carrier gas flowed through the chamber during decontamination is monitored for levels of one or more contaminants, as indicated at step 304 in the figure. This monitoring is carried out using standard gas-measurement instruments, such as available from Balazs Analytical Service (CA), Ametek Process Instruments (DE), Cosa Instruments Corp. (NY), Meeco (PA), Midac Corp (CA), Sartorius Corp. NY), or Vaisal, Inc. MA).

These steps are continued, through the logic of 306, until measured level of contaminant is below a preselected certification level. Levels of oxygen, moisture, and THC contaminants that are desired, in a pre-certified chamber, will typically be in the range 1 ppb (parts per billion) to 100 ppm (part per million), and preferably in the range 10-100 ppb, at the lower end of the range, and 1 to 10 ppm, at the upper end of the range. When the desired thresholds are reached, the outgassing steps are stopped, and the chamber is filled with an inert gas, and sealed for shipping, as indicated at 308.

Additionally, a Certification or other appropriate documentation may be attached to the process chamber as illustrated in step 310, and may indicate the level of contamination measured during the final step and may indicate compliance with the desired result. The customer may use this documentation as an indication of the initial contamination level as the process chamber is used in subsequent manufacturing, assembly, or semiconductor device manufacturing procedures.

The decontamination and/or pre-certification steps described above may be implemented at any step in the semiconductor process equipment manufacturing cycle. The procedures may be implemented at the chamber fabrication entity before the chamber body ships. This may serve to certify the contamination level of the process chamber body at the point of fabrication. The process chamber body fabrication entity may enjoy the benefits of improved cleaning procedures, enhanced product quality, greater customer satisfaction, and the like.

The procedures may be implemented at the subassembly entity after the subassembly activity is complete and before the subassembly is shipped to the OEM. This may serve to certify the contamination level of the process chamber at the point of subassembly and may indicate the change in contamination levels during the subassembly process. The subassembly entity may enjoy the benefits of improved assembly procedures, identification of steps that introduce additional contamination, enhanced product quality, greater customer satisfaction, and the like.

The procedures may be implemented at the OEM after the final assembly and test activity is complete and before the system is shipped to the customer. This may serve to certify the contamination level of the process chamber at the point of final assembly and test and may indicate the change in contamination levels during the final assembly and test process. The OEM may enjoy the benefits of improved final assembly and test procedures, identification of steps that introduce additional contamination, enhanced product quality, greater customer satisfaction, and the like.

The procedures may be implemented at the customer manufacturing facility after the installation activity is complete and before the system begins qualification. This may serve to certify the contamination level of the process chamber at the point of installation and may indicate the change in contamination levels during the installation process. The OEM may enjoy the benefits of improved installation procedures, identification of steps that introduce additional contamination, enhanced product quality, greater customer satisfaction, reduced troubleshooting time, and the like.

The procedures may be implemented at the customer manufacturing facility after a maintenance activity is complete and before the system begins qualification. This may serve to certify the contamination level of the process chamber at the point of maintenance and may indicate the change in contamination levels during the maintenance process. The customer may enjoy the benefits of improved maintenance procedures, identification of steps that introduce additional contamination, enhanced product quality, reduced downtime, reduced troubleshooting time, and the like.

FIG. 4 is a schematic view of a semiconductor processing system constructed in accordance with an embodiment of the invention. The processing chamber in the system, indicated at 400, includes a heating element 402 for heating the chamber to a desired outgassing temperature, and a temperature sensor 404 for monitoring chamber temperature. The chamber is supplied purge gas from a gas source 408 connected to the chamber through a gas-supply line 410, under the control of a gas-valve 412. The purge gas is vented from the chamber through an exhaust line 414, and the line houses one or more gas sensors, such as sensor 416, for monitoring a selected contaminant gas carried in the carrier gas as it exits the chamber, through a monitor 418.

The components of the system are controlled by a controller 420 which is operatively connected to purge-gas valve 412, for controlling the flow of purge gas into the chamber, and to heating element 402, for controlling the temperature within the chamber, in response to the temperature information received by the controller from sensor 404. The controller also receives from monitor 418, signals related to the levels of one of one contaminant gases present in the carrier gas at the exhaust side of the chamber. As described above, and further with respect to FIGS. 5A and 5B, the controller operates to (i) heat the interior of the chamber to a temperature effective to desorb each such gas contaminant from interior surface of the chamber, (ii) during this heating, and by its control over valve 412, to direct a stream of inert gas stream through the chamber, thus to entrain desorbed contaminant gas in the gas stream, and (iii) continuing step (i)-(ii) for a period of time calculated, on the basis of a predetermined rate of desorption of each contaminant gas under the conditions of step (i) and (ii), to achieve a preselected level of the contaminant gas or gasses, and typically the gas having the slowest rate of desorption from the chamber walls. The controller includes a processor that may employ a computer readable code for carrying out the steps just described.

FIGS. 5A and 5B illustrate an embodiment of the invention for optimizing the conditions needed to achieve desired below-threshold levels of chamber contaminants, e.g., for carrying out the certification method described above. In this embodiment, a chamber is outgasssed, under selected conditions of heating and purging with an inert carrier gas, as described above and shown in FIG. 5A at 510. During this period of heating and purging, beginning from an initial time tᵢ, the carrier purge gas is monitored for levels of contaminants, as at 512, until a desired below-threshold level of all contaminants is reached at a finish time t_{f}. The data on the time-dependent reduction of the contaminant gasses is then used, according to standard curve-plotting methods, to determine a rate of decontamination of each gas at temperature and purge-gas flow rate employed.

This determined rate can then be used to calculate, from any given initial measured gas level, the minimum time tₘ required to reach a desired below-threshold level of the gas, at the selected outgassing conditions. FIG. 5B illustrates how this rate is used in an embodiment of the invention for optimizing the time needed for chamber decontamination and/or certification. Initially a chamber to be decontaminated and/or certified is subject to selected temperature and gas-flow conditions, as above and as indicated at 516, and an initial measurement of gas contaminants is made at initial time tᵢ, at 518. Using the predetermined rate of decontamination under the selected conditions, (514 in FIG. 5A), the method calculates the minimum time tₘ needed to achieve the desired below-threshold values, at 520. The outgassing conditions are then continued, with or without continued monitoring, until the time tₘ is reached. As will be appreciated, the method allows an existing system to be brought to certification level of contamination in a minimum time, to minimize down time of the system. The optimized time for decontamination calculated as above may be applied in a single-run decontamination, as described, or the optimized times may be determined for each of two or more separate runs.

Although various embodiments which incorporate the teachings of the present invention have been shown and described in detail herein, those skilled in the art can readily devise many other varied embodiments that still incorporate these teachings.

It is claimed:

1. A process chamber designed for use in a semiconductor processing system having one or more such chambers, where each chamber in the system is designed to receive a substrate and a process gas that acts upon the substrate, as part of a process for producing a semiconductor device, said chamber being pre-certified to contain no more than a predetermined threshold concentration of a contaminant that is known to adversely effect the performance characteristics of such a device, when produced in such a process, and sealed with an inert gas to prevent exposure of the chamber to the atmosphere prior to being incorporated into said system.

2. The chamber of claim 1, which is pre-certified to contain no more than a preselected level of one or more of total hydrocarbons (THCs), oxygen, and moisture.

3. The chamber of claim 2, which is pre-certified to contain no more than a preselected level of the contaminant gas selected from within the range of 1 ppb to 100 ppm.

4. A method for pre-certifying a process chamber designed for use in a semi-conductor processing system containing one or more such chambers, comprising
(i) setting a pre-certification level of each of one or more contaminant gases, said level being below that at which a semi-conductor processing step designed to be carried out in that chamber may be adversely affected,
(ii) heating the interior of the chamber to a temperature effective to desorb each such gas contaminant from interior surface of the chamber,
(iii) during said heating, directing a stream of inert gas stream through the chamber, thus to entrain desorbed contaminant gas in the gas stream,
(iv) measuring the level of each such contaminant gas entrained in the gas stream from step (c),
(v) continuing steps (ii)-(iv) until the level of each such contaminant is at or below the pre-certification level, and
(vi) sealing the chamber with an inert gas to prevent exposure of the chamber to the atmosphere.

5. The method of claim 4, wherein steps (ii)-(iv) are carried out to achieve a pre-certification level in a selected range between 1 ppb and 100 ppm, of one or more of total hydrocarbons (THCs), oxygen, and moisture.

6. The method of claim 4, wherein step (ii) includes heating interior surfaces of the chamber to a temperature between about 100°-400° C.

7. The method of claim 6, wherein step (ii) includes heating interior surfaces of the chamber to a temperature between about 150°-250° C.

8. A method of minimizing the time required to decontaminate a process chamber designed for use in a semi-conductor processing system containing one or more such chambers, to achieve a preselected level of one or more contaminant gases, said preselected level of contaminant gas being below that at which a semi-conductor processing step designed to be carried out in that chamber may be adversely affected, comprising
(i) heating the interior of the chamber to a temperature effective to desorb each such gas contaminant from interior surface of the chamber,
(ii) during said heating, directing a stream of inert gas stream through the chamber, thus to entrain desorbed contaminant gas in the gas stream,
(iii) at each of a plurality of time points following the initiation of step (i), measuring the level of each such contaminant gas entrained in the gas stream from step (ii), thus to determine the rate of desorption of each contaminant gas under the conditions of steps (i) and (ii), and
(iv) calculating from the rate of desorption of each contaminant gas determined in step (iii), the minimum time required to achieve such preselected level of the contaminant gas having the slowest rate of desorption from the chamber walls.

9. The method of claim 8, wherein the contaminant gas measured in step (iii) is one or more of total hydrocarbons (THCs), oxygen, and moisture, and the preselected level of contaminant gas is less than a preselected level in the range 1 ppb to 100 ppm.

10. The method of claim 8, wherein step (i) includes heating interior surfaces of the chamber to between about 150°-250° C.

11. A method of decontaminating a process chamber designed for use in a semi-conductor processing system containing one or more such chambers, to achieve a preselected level one or more contaminant gases, said preselected level of a contaminant gas being below that at which a semi-conductor processing step designed to be carried out in that chamber may be adversely affected, comprising
(i) heating the interior of the chamber to a temperature effective to desorb each such gas contaminant from interior surface of the chamber,
(ii) during said heating, directing a stream of inert gas stream through the chamber, thus to entrain desorbed contaminant gas in the gas stream,
(iii) continuing step (i)-(ii) for a period of time calculated, on the basis of a predetermined rate of desorption of each contaminant gas under the conditions of step (i) and (ii), to achieve such preselected level of the contaminant gas having the slowest rate of desorption from the chamber walls.

12. The method of claim 11, wherein the contaminant gas is one or more of total hydrocarbons (THCs), oxygen, and moisture, and the preselected level of contaminant gas is less than a preselected level in the range 1 ppb to 100 ppm.

13. The method of claim 11, wherein step (i) includes heating interior surfaces of the chamber to between about 150°-250° C.

14. A semiconductor processing system comprising:
(a) a process chamber;
(b) a heater for heating interior walls of the process chamber to a selected temperature between about 100°-400° C.,
(c) a purge-gas supply line for directing an inert purge gas through the chamber,
(d) a device for measuring a concentration of a contaminant in the process chamber; and
(e) a controller operatively connected to the heater, supply line and measuring device, for periodically reducing the level of selected contaminant gases in the chamber to below-threshold levels, by the steps of:
(i) heating the interior of the chamber to a temperature effective to desorb each such gas contaminant from interior surface of the chamber,
(ii) during said heating, directing a stream of inert gas stream through the chamber, thus to entrain desorbed contaminant gas in the gas stream,
(iii) continuing step (i)-(ii) for a period of time calculated, on the basis of a predetermined rate of desorption of each contaminant gas under the conditions of step (i) and (ii), to achieve such preselected level of the contaminant gas having the slowest rate of desorption from the chamber walls.

15. The method of claim 14, wherein the contaminant gas measured is one or more of total hydrocarbons (THCs), oxygen, and moisture, and the preselected level of contaminant gas is less than a preselected level in the range 1 ppb to 100 ppm.

16. The method of claim 14, wherein step (i) includes heating interior surfaces of the chamber to between about 100°-400° C.

17. In a semiconductor processing system having a process chamber, a heater for heating interior walls of the process chamber to a selected temperature between about 100°-400° C., a purge-gas supply line for directing an inert purge gas through the chamber, and a device for measuring a concentration of a contaminant in the process chamber; a controller operatively connected to the heater, supply line and measuring device, for periodically reducing the level of selected contaminant gases in the chamber to below-threshold levels, by the steps of:
(i) heating the interior of the chamber to a temperature effective to desorb each such gas contaminant from interior surface of the chamber,
(ii) during said heating, directing a stream of inert gas stream through the chamber, thus to entrain desorbed contaminant gas in the gas stream,
(iii) continuing step (i)-(ii) for a period of time calculated, on the basis of a predetermined rate of desorption of each contaminant gas under the conditions of step (i) and (ii), to achieve such preselected level of the contaminant gas having the slowest rate of desorption from the chamber walls.

18. In a semiconductor processing system having a process chamber, a heater for heating interior walls of the process chamber to a selected temperature between about 100°-400° C., a purge-gas supply line for directing an inert purge gas through the chamber, and a device for measuring a concentration of a contaminant in the process chamber; and a controller operatively connected to the heater, supply line and measuring device, computer-readable code under the control of a microprocessor in the controller, for directing the controller in periodically reducing the level of selected contaminant gases in the chamber to below-threshold levels, by the steps of:
(i) heating the interior of the chamber to a temperature effective to desorb each such gas contaminant from interior surface of the chamber,
(ii) during said heating, directing a stream of inert gas stream through the chamber, thus to entrain desorbed contaminant gas in the gas stream,
(iii) continuing step (i)-(ii) for a period of time calculated, on the basis of a predetermined rate of desorption of each contaminant gas under the conditions of step (i) and (ii), to achieve such preselected level of the contaminant gas having the slowest rate of desorption from the chamber walls.
